(19) United States
(12) Patent Application Publication
(10) Pub. No.: US 2025/0391766 A1
(43) Pub. Date: Dec. 25, 2025

(54) ULTRA-THICK METAL ROUTING STRUCTURE AND FORMING METHOD THEREOF

(71) Applicant: Taiwan Semiconductor Manufacturing Company, Ltd., Hsinchu (TW)

(72) Inventors: Chun-Hao LIN, Hsinchu (TW); Yu-Jen WANG, Hsinchu (TW); Wei-Tao TSAI, Hsinchu (TW); Kai-Yun YANG, Hsinchu (TW); Chun-Hao CHOU, Hsinchu (TW)

(73) Assignee: Taiwan Semiconductor Manufacturing Company, Ltd., Hsinchu (TW)

(21) Appl. No.: 18/752,241

(22) Filed: Jun. 24, 2024

(51) Int. Cl. H01L 23/528; H01L 23/00

(52) U.S. Cl. CPC H01L 23/528; H01L 24/08; H01L 24/80; H01L 2224/08145; H01L 2224/80895; H01L 2924/3511

(57) ABSTRACT

A method of manufacturing a semiconductor device includes providing a first semiconductor substrate and forming a plurality of first metal lines extending along a first direction in the first semiconductor substrate. Each of the plurality of first metal lines includes a plurality of first discrete portions spaced along the first direction. The method further includes providing a second semiconductor substrate, and forming a second metal line below each of the plurality of first metal lines and extending along the first direction in the second semiconductor substrate. The second metal line includes a plurality of second discrete portions spaced along the first direction and the plurality of second discrete portions and the plurality of first discrete portions are alternately staggered along the first direction. The method also includes forming a bonding connector connecting the plurality of second discrete portions to a corresponding first metal line of the plurality of first metal lines.

### BACKGROUND

As consumer devices have gotten smaller and smaller in response to consumer demand, the individual components of these devices have necessarily decreased in size as well. Semiconductor devices, which make up a major component of devices such as mobile phones, computer tablets, and the like, have been pressured to become smaller and smaller, with a corresponding pressure on the individual devices (e.g., transistors, resistors, capacitors, and etc.) within the semiconductor devices to also be reduced in size. To achieve a smaller horizontal or lateral footprint of the semiconductor die package and/or to increase the density of the semiconductor die package, various semiconductor device packaging techniques may be used to incorporate one or more semiconductor dies into the semiconductor die package. Some three-dimensional (3D) integrated circuit (IC) device structures, such as wafer-on-wafer (WoW) structures, are formed by stacking and bonding multiple IC devices (i.e., chips) at a semiconductor wafer level. The 3D IC device structures may provide improved integration density and have advantages, such as greater speeds and greater bandwidths, due to the decreased lengths of interconnects between the stacked chips.

One enabling technology that is used in the manufacturing processes of semiconductor devices is forming an ultra-thick metal (UTM) layer for inductors of radio frequency (RF) integrated circuits, antennas with low loss requirements, high voltage (HV) integrated circuits for power supplies or display drivers, and high current power lines with a low impedance path and minimizing voltage drop requirements.

However, traditional semiconductor processing techniques do not readily scale for use with ultra-thick metal (UTM). For example, as wafer-on-wafer technology becomes more popular, wafer warpage induced by metal stress due to ultra-thick metal long lines is a major process challenge. The wafer bonding process and the following silicon wafer backside process may be impacted by the induced warpage on the wafers. As such, advances in the field of forming a structure with ultra-thick metal routing are necessary to reduce the warpage and prevent distortion of the wafer due to metal stress, and further improvements are needed in order to meet the desired design criteria such that the march towards smaller and smaller components may be maintained.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a process flow of manufacturing a semiconductor device according to embodiments of the disclosure.

FIG. 2 shows a perspective view of a semiconductor device according to embodiments of the disclosure.

FIGS. 3A, 3B, and 3C show a bottom view and sectional views of a semiconductor device according to embodiments of the disclosure.

FIG. 4 illustrates a process flow of manufacturing a semiconductor device according to embodiments of the disclosure.

FIG. 5 shows a perspective view of a semiconductor device according to embodiments of the disclosure.

FIGS. 6A, 6B, 6C, 6D, and 6E show a bottom view and sectional views of a semiconductor device according to embodiments of the disclosure.

FIG. 7 illustrates a process flow of manufacturing a semiconductor device according to embodiments of the disclosure.

FIG. 8 shows a perspective view of a semiconductor device according to embodiments of the disclosure.

FIGS. 9A, 9B, 9C, 9D, and 9E show a bottom view and sectional views of a semiconductor device according to embodiments of the disclosure.

### DETAILED DESCRIPTION

It is to be understood that the following disclosure provides many different embodiments, or examples, for implementing different features of the disclosure. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.”

Ultra-thick metal (UTM) routing is used to reduce circuit design voltage drop (IR drop) on the back-end-of-the-line (BEOL). However, ultra-thick metal long lines are usually routed in one direction and will worsen and induce unbalanced wafer warpage on the surface of the wafer due to metal stress. As such, wafer-on-wafer (WoW) structures may be affected by the worsened and unbalanced wafer warpage when applying the ultra-thick metal method to the silicon process. For example, due to the significant wafer warpage, the wafer bonding process has challenging issues, such as wafer bond slip, bubbles between the interface of stacked wafers, and die-to-die alignment accuracy. Additionally, the silicon wafer backside processes, such as lithography alignment, may also be impacted due to wafer distortion coming from poor wafer bonding performance, and/or packaging difficulty. The stacked-wafer backside pressure fault on electrostatic chucks may also occur as a result of the significant stacked-wafer warpage. Embodiments of this disclosure provide an improved ultra-thick metal (UTM) routing structure and methods of forming the same, thereby reducing the wafer warpage due to the metal stress. For example, an ultra-thick metal (UTM) with a cut-line structure reduces the wafer warpage and releases the stress, such that the performance of the wafer bonding and the silicon wafer backside process is improved.

In some embodiments of the present disclosure, ultra-thick metal (UTM) with a cut-line structure is formed. It will be understood by those skilled in the art that the disclosure could be applied to the formation of other structures.

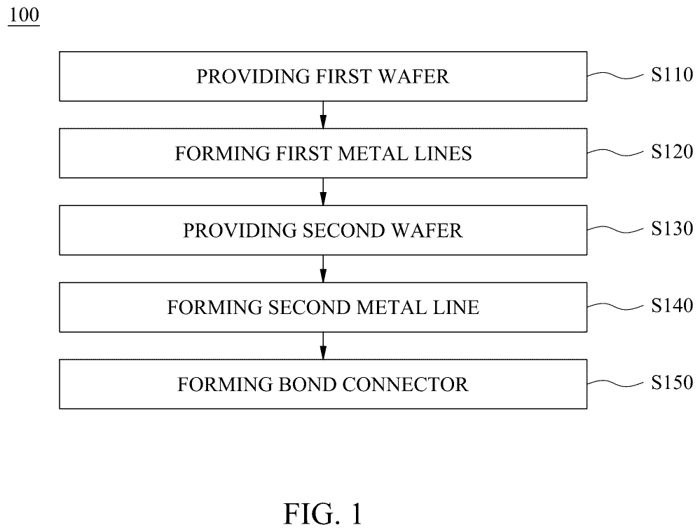

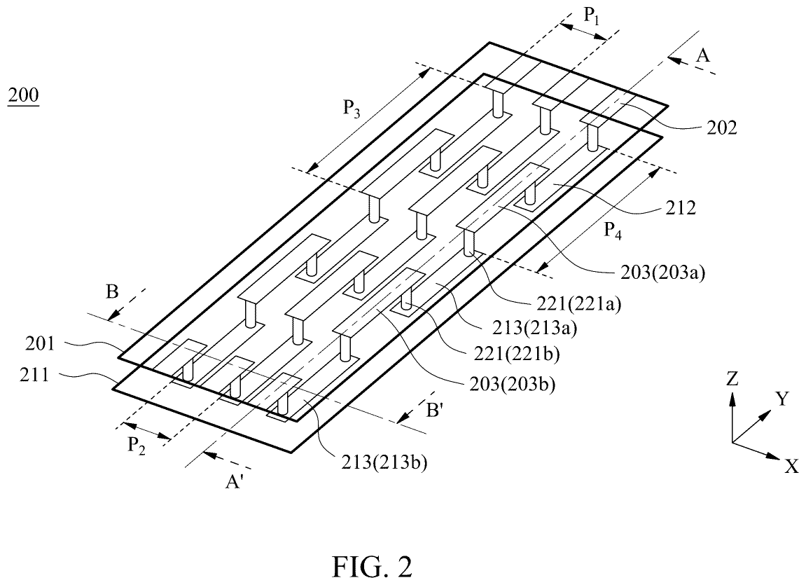

FIG. 1 illustrates a process flow 100 of manufacturing a semiconductor device according to embodiments of the disclosure. FIG. 2 shows a perspective view of a semiconductor device 200 according to embodiments of the disclosure. In some embodiments, as shown in FIG. 2, a first semiconductor wafer 201 is provided in operation S110. A portion of the first semiconductor wafer 201 is illustrated in FIG. 2 to clarify and better illustrate the features of the present disclosure.

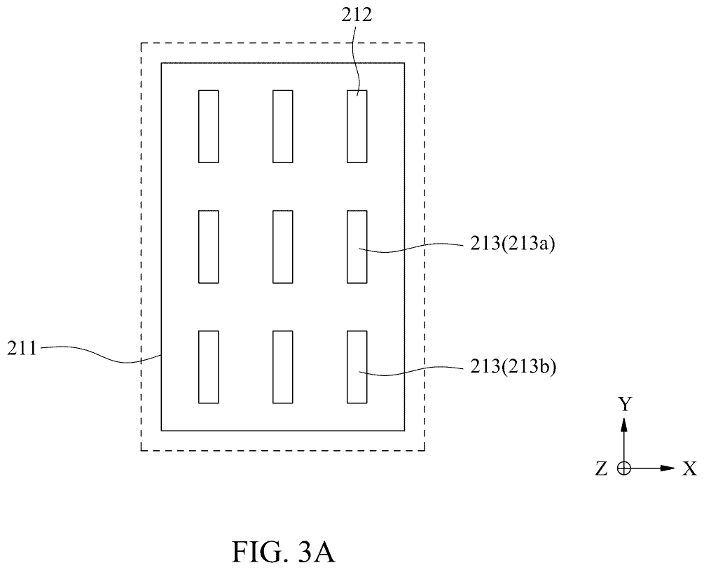

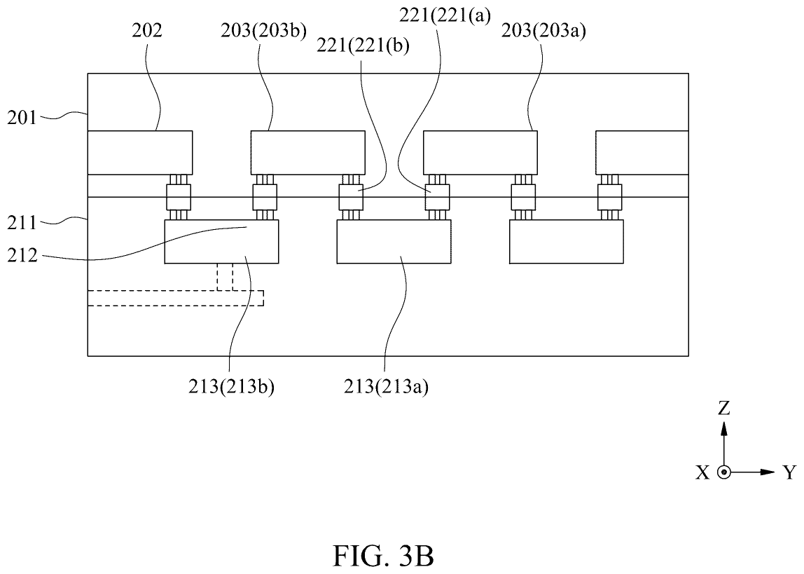

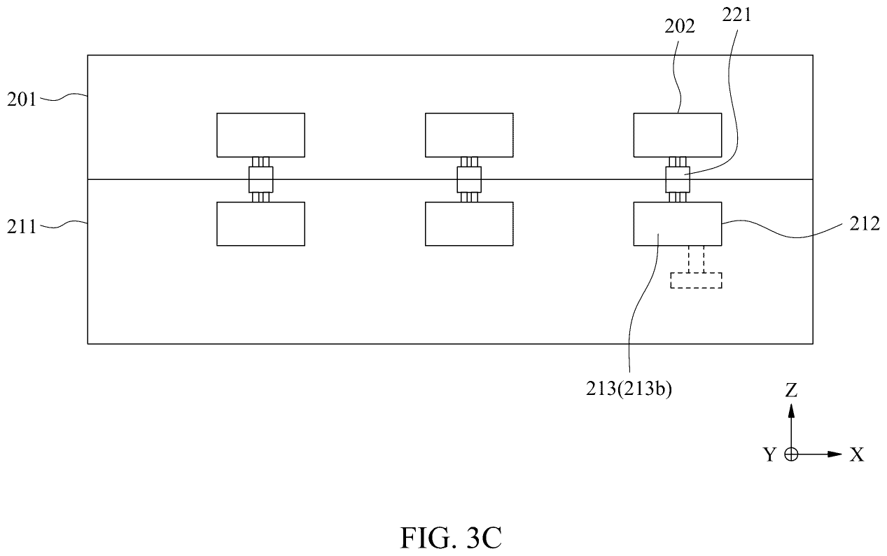

FIGS. 3A, 3B, and 3C show a bottom view and sectional views of the semiconductor device 200 according to embodiments of the disclosure. FIG. 3A shows a bottom view of the semiconductor device 200 as shown in FIG. 2. FIG. 3B shows a cross-sectional view of the semiconductor device 200 cut along the AA′ plane as shown in FIG. 2. FIG. 3C shows a cross-sectional view of the semiconductor device 200 cut along the BB′ plane as shown in FIG. 2.

In some embodiments, the first semiconductor wafer 201 includes a first substrate (not shown) and a first dielectric layer (not shown) on the first substrate. The first substrate may be made of silicon, although it may also be formed of other group III, group IV, and/or group V elements such as silicon, germanium, gallium, arsenic, or combinations thereof. In some embodiments, the first dielectric layer is made of silicon oxide, silicon nitride, silicon carbide, silicon oxynitride, combinations thereof, and/or the like.

In some embodiments, first electrical circuits are formed on the first substrate. The first electrical circuits may be any type of circuitry suitable for a particular application. For example, the first electrical circuits may include various N-type metal-oxide semiconductor (NMOS) and/or P-type metal-oxide semiconductor (PMOS) devices, capacitors, resistors, diodes, photo-diodes, fuses, and/or the like.

Referring back to FIG. 1, in some embodiments, as shown in FIG. 2, FIG. 3B, and FIG. 3C, a plurality of first metal lines 202 are formed in the first semiconductor wafer 201 in operation S120. For example, as shown in FIG. 2, the plurality of first metal lines 202 extend along a y-direction. The plurality of first metal lines 202 may be distributed in an x-direction. The x-direction may be perpendicular to the y-direction. In some embodiments, an angle between the x-direction and the y-direction is an acute angle.

In some embodiments, the plurality of first metal lines 202 are uniformly distributed in the x-direction. In some embodiments, the plurality of first metal lines 202 have multiple sets of different first-line pitches along the x-direction.

In some embodiments, the plurality of first metal lines 202 are formed by forming trenches or vias in the first semiconductor wafer 201 according to a designed pattern and then filling the trenches or vias with a conductive material. It will be understood by those skilled in the art that other methods of forming the plurality of first metal lines 202 could be applied to the first semiconductor wafer 201.

In some embodiments, the plurality of first metal lines 202 have a thickness in a range from 1 μm to 20 μm. In some embodiments, the plurality of first metal lines 202 have a thickness in a range from 2 μm to 10 μm.

In some embodiments, the plurality of first metal lines 202 include copper. In some embodiments, the plurality of first metal lines 202 include copper, aluminum, gold, silver, silicon, combinations thereof, and/or the like.

In some embodiments, as shown in FIG. 2 and FIG. 3B, each of the plurality of first metal lines 202 includes a plurality of first discrete portions 203 (e.g., 203a and 203b). In some embodiments, each of the plurality of first discrete portions 203 (e.g., 203a) is separated from adjacent first discrete portions (e.g., 203b).

In some embodiments, the plurality of first discrete portions 203 (e.g., 203a and 203b) are spaced from each other and uniformly distributed in the y-direction. In some embodiments, the plurality of first discrete portions 203 (e.g., 203a and 203b) have multiple sets of first discrete portion pitches along the y-direction.

Referring back to FIG. 1, in some embodiments, as shown in FIG. 2, a second semiconductor wafer 211 is provided in operation S130.

In some embodiments, the second semiconductor wafer 211 includes a second substrate (not shown) and a second dielectric layer (not shown) on the second substrate. The second substrate may be made of silicon, although it may also be formed of other group III, group IV, and/or group V elements such as silicon, germanium, gallium, arsenic, or combinations thereof. In some embodiments, the second dielectric layer is made of silicon oxide, silicon nitride, silicon carbide, silicon oxynitride, combinations thereof, and/or the like.

In some embodiments, second electrical circuits are formed on the second substrate. The second electrical circuits may be any type of circuitry suitable for a particular application. For example, the second electrical circuits may include various N-type metal-oxide semiconductor (NMOS) and/or P-type metal-oxide semiconductor (PMOS) devices, capacitors, resistors, diodes, photo-diodes, fuses, and/or the like.

Referring back to FIG. 1, in some embodiments, as shown in FIG. 2, FIG. 3A, FIG. 3B, and FIG. 3C, a plurality of second metal lines 212 are formed in the second semiconductor wafer 211 in operation S140. For example, the plurality of second metal lines 212 extend along the y-direction. The plurality of second metal lines 212 are distributed in the x-direction. A portion of the second semiconductor wafer 211 is illustrated in FIG. 2 to clarify and better illustrate the features of the present disclosure.

In some embodiments, as shown in FIG. 2 and FIG. 3C, each of the plurality of second metal lines 212 is positioned below a corresponding first metal line of the plurality of first metal lines 202. For example, each of the plurality of second metal lines 212 aligns with the corresponding first metal lines of the plurality of first metal lines 202 along the z-direction.

In some embodiments, as shown in FIG. 2 and FIG. 3A, the plurality of second metal lines 212 are uniformly distributed in the x-direction. In some embodiments, along the x-direction, a second pitch P₂ of the plurality of second metal lines 212 equals a first pitch P₁ of the plurality of first metal lines 202. In some other embodiments, the plurality of second metal lines 212 have multiple sets of different second line pitches along the x-direction.

In some embodiments, the plurality of second metal lines 212 are formed by forming trenches or vias in the second semiconductor wafer 211 according to a designed pattern and then filling the trenches or vias with a conductive material. It will be understood by those skilled in the art that other methods of forming the plurality of second metal lines 212 could also be applied to the second semiconductor wafer 211.

In some embodiments, the plurality of second metal lines 212 have a thickness in a range from 1 μm to 20 μm. In some embodiments, the plurality of second metal lines 212 have a thickness in a range from 2 μm to 10 μm.

In some embodiments, the plurality of second metal lines 212 include copper. In some embodiments, the plurality of second metal lines 212 include copper, aluminum, gold, silver, silicon, combinations thereof, and/or the like.

In some embodiments, each of the plurality of second metal lines 212 includes a plurality of second discrete portions 213 (e.g., 213a and 213b). In some embodiments, each of the plurality of second discrete portions 213 (e.g., 213a) is separated from adjacent second discrete portions (e.g., 213b). In some embodiments, as shown in FIG. 2 and FIG. 3B, the plurality of second discrete portions 213 (e.g., 213a and 213b) and the plurality of first discrete portions 203 (e.g., 203a and 203b) are alternately staggered along the first direction.

In some embodiments, the plurality of second discrete portions 213 are spaced from each other and uniformly distributed in the y-direction. In some embodiments, along the y-direction, a fourth portion pitch P₄ of the plurality of second discrete portions 213 equals a third portion pitch P₃ of the plurality of first discrete portions 203. In some embodiments, the plurality of second discrete portions 213 (e.g., 213a and 213b) have multiple sets of second discrete portion pitches along the y-direction.

Referring back to FIG. 1, in some embodiments, as shown in FIG. 2, FIG. 3B, and FIG. 3C, bonding connectors 221 are formed in operation S150.

In some embodiments, the bonding connectors 221 are formed to connect each of the plurality of first discrete portions 203 and adjacent first discrete portions 203 through the plurality of second discrete portions 213. For example, a first discrete portion 203a is connected to a corresponding second discrete portion 213a through a first bonding connector 221a in some embodiments. Then, the corresponding second discrete portion 213a is connected to the adjacent first discrete portion 203b through a second bonding connector 221b. In some embodiments, the plurality of first discrete portions 203 of a first metal line of the plurality of first metal lines 202 are electrically connected with each other.

In some embodiments, the bonding of bonding connectors 221 to the first semiconductor wafer 201 and the second semiconductor wafer 211 is achieved through a wafer-on-wafer (WoW) bonding process. In the wafer-on-wafer bonding process, the first semiconductor wafer 201 is bonded to the second semiconductor wafer 211, and the connectors 221 are bonded to the plurality of first metal lines 202 and the plurality of second metal lines 212 through metal-to-metal direct bonding. In some embodiments, the first discrete portion 203a and the corresponding second discrete portion 213a are bonded to the first bonding connector 221athrough metal-to-metal direct bonding. In some embodiments, an annealing process is performed after the wafer-on-wafer bonding process to further strengthen the bonding between the first semiconductor wafer 201 and the second semiconductor wafer 211. Through the wafer-on-wafer bonding process, the bonding connector 221 may connect each of the plurality of first discrete portions 203 of a first metal line 202 and the plurality of second discrete portions 213 of a corresponding second metal line 212.

In some embodiments, the bonding connectors 221 are made of a conductive material such as solder, copper, aluminum, gold, nickel, silver, palladium, tin, a combination thereof, and/or the like.

In ultra-thick metal (UTM) with cut-line structures, such as the plurality of discrete portions (e.g., 203 and 213) instead of long continuous metal lines extending in one direction, the metal stress can be released, thereby reducing wafer warpage and achieving balance. For a 12-inch wafer with related continuous metal lines having a thickness of 3.5 μm, the warpage of the wafer is about 280 μm in the x-direction and about 90 μm in the y-direction. The bow bias of the wafer due to the warpage is about 190 μm. In contrast, in some embodiments of the present disclosure, for a 12-inch wafer with metal lines having a thickness of 3.5 μm, the warpage of the wafer is reduced to about 93 μm in the x-direction and about −11 μm in the y-direction. The bow bias of the wafer due to the warpage is about 104 μm. The amount of warpage of the wafer is reduced by about 67% in the x-direction and about 112% in the y-direction compared to warpage in conventional wafers. The bow bias is reduced by about 45% of bow bias in conventional wafers.

For a pre-bonding wafer with related continuous metal lines, the warpage of the pre-bonding wafer is about 285 μm in the x-direction and about 89 μm in the y-direction. The bow bias of the pre-bonding wafer due to the warpage is about 196 μm. In contrast, in some embodiments of the present disclosure, the warpage of the pre-bonding wafer is reduced to about 56 μm in the x-direction and about −51 μm in the y-direction. The bow bias of the pre-bonding wafer due to the warpage is about 107 μm. The amount of warpage of the wafer is reduced by about 80% in the x-direction and about 157% in the y-direction compared to warpage in conventional pre-bonding wafer. The bow bias is reduced by about 45% of bow bias in the conventional pre-bonding wafer. According to some embodiments of the present disclosure, the bow value of the wafer warpage in the y-direction is reversed to be negative. In other words, the bow is bent in an opposite direction compared to the warpage in conventional pre-bonding wafer. The pre-bonding wafer may have other chips or structures integrated, and the embodiments including a negative warpage may further release the stress due to those additional chips or structures.

For a thinned-down wafer-on-wafer structure with conventional continuous metal lines, the warpage of the wafer-on-wafer structure is about 377 μm in the x-direction and about 86 μm in the y-direction. The bow bias of the thinned-down wafer-on-wafer structure due to the warpage is about 291 μm. In contrast, in some embodiments of the present disclosure, the warpage of the thinned-down wafer-on-wafer structure is reduced to about −28 μm in the x-direction and about −161 μm in the y-direction. The bow bias of the thinned-down wafer-on-wafer structure due to the warpage is about 133 μm. The amount of warpage of the thinned-down wafer-on-wafer structure is reduced by about 107% in the x-direction and about 287% in the y-direction compared to warpage in conventional thinned-down wafer-on-wafer structure. The bow bias is reduced by about 54% of bow bias in the conventional thinned-down wafer-on-wafer structure.

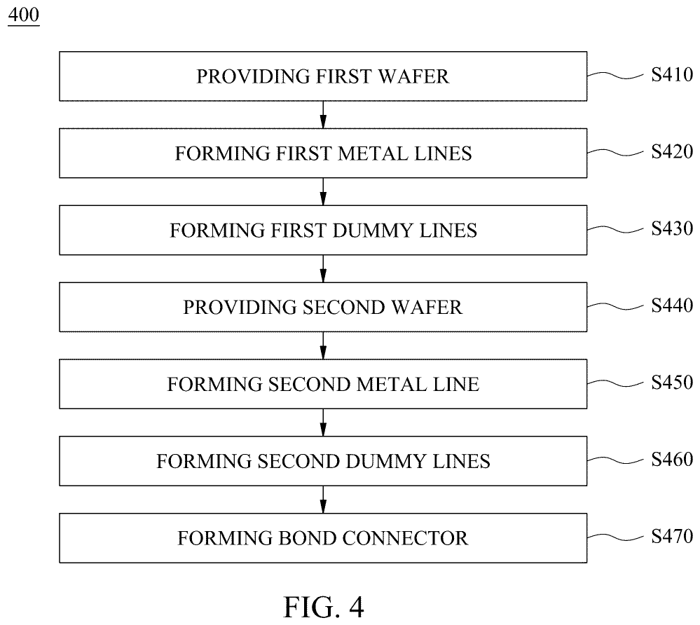

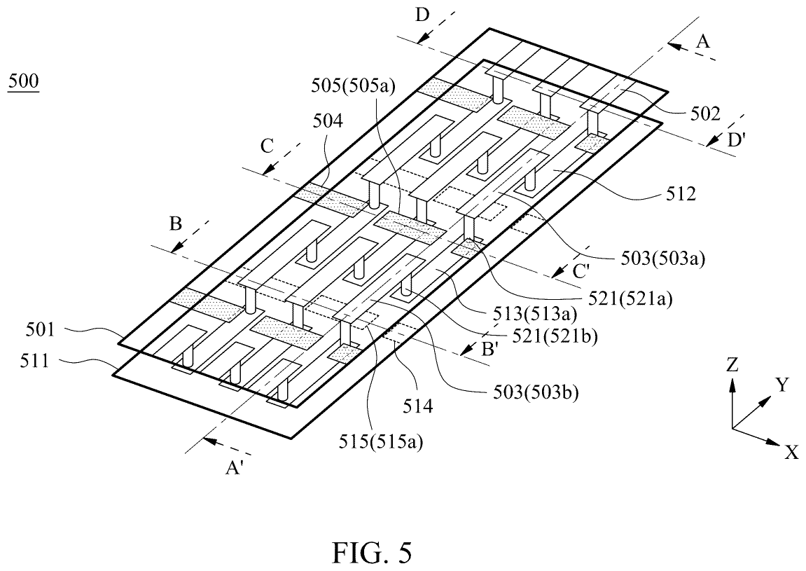

FIG. 4 illustrates a process flow 400 of manufacturing a semiconductor device according to embodiments of the disclosure. FIG. 5 shows a perspective view of a semiconductor device 500 according to embodiments of the disclosure. In some embodiments, as shown in FIG. 5, a first semiconductor wafer 501 is provided in operation S410. A portion of the first semiconductor wafer 501 is illustrated in FIG. 5 to clarify and better illustrate the features of the present disclosure.

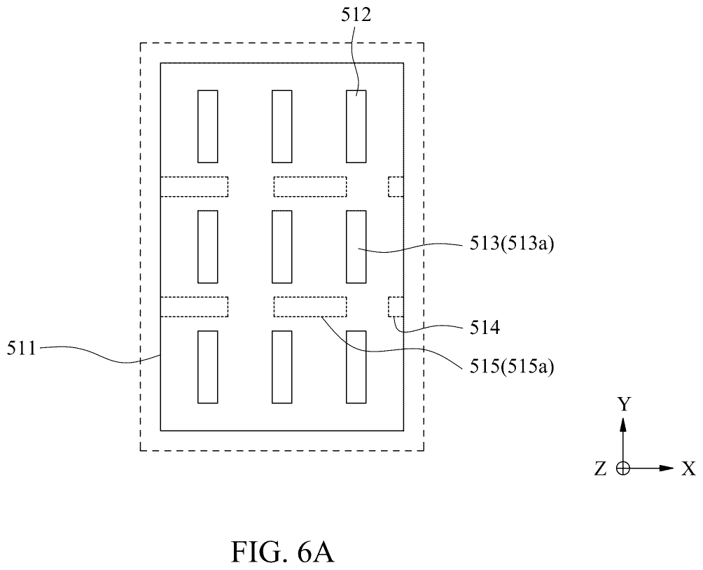

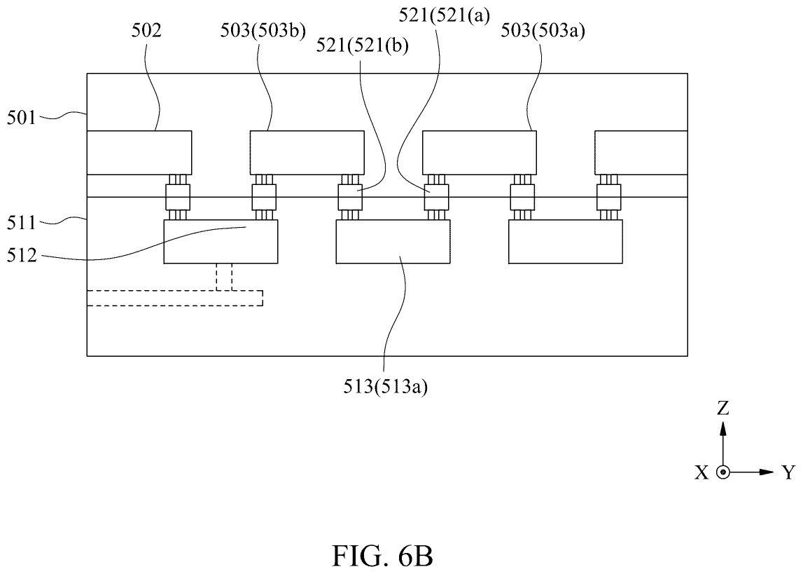

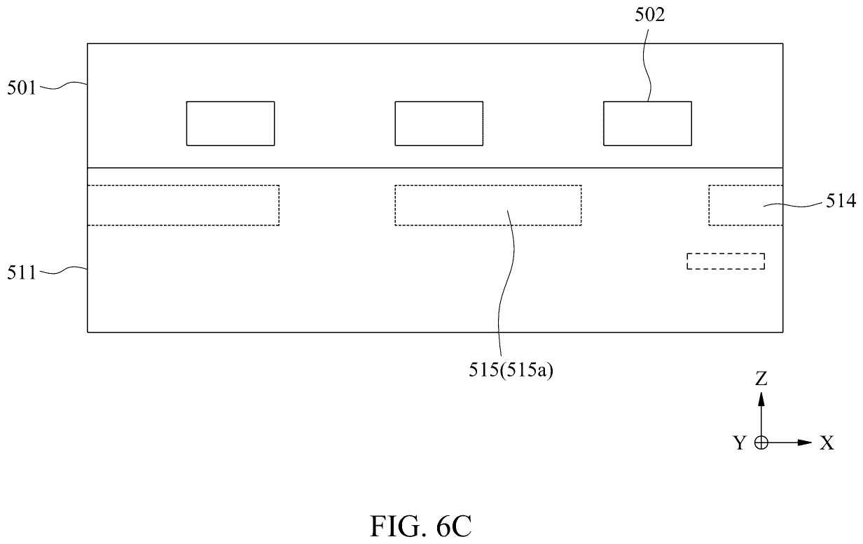

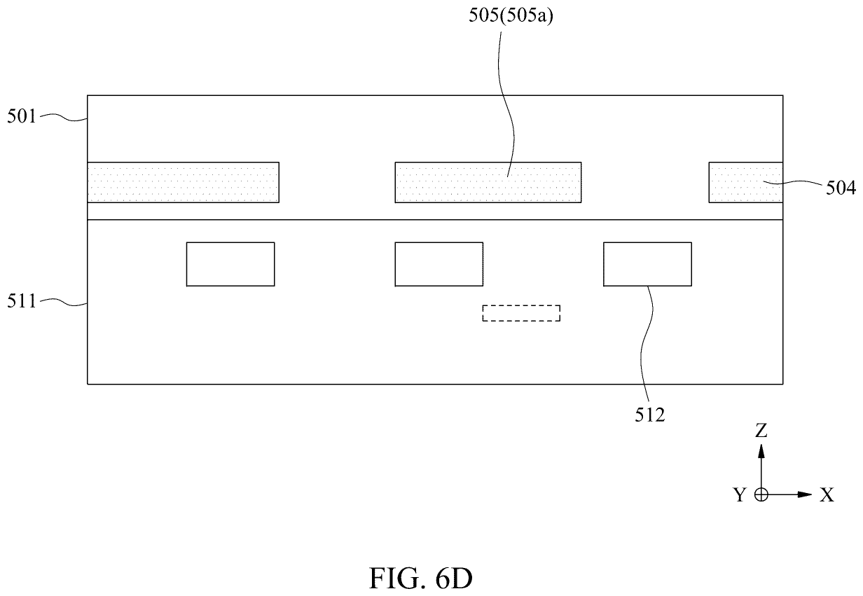

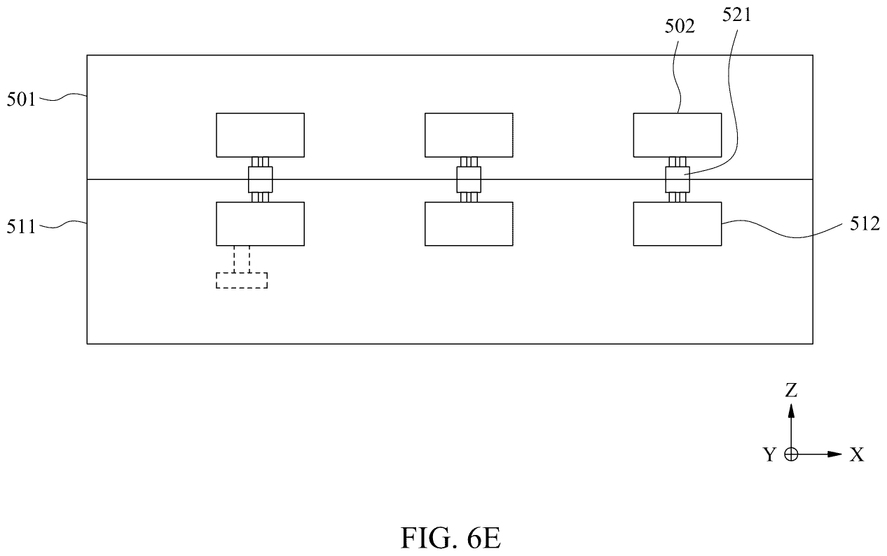

FIGS. 6A, 6B, 6C, 6D, and 6E show a bottom view and sectional views of the semiconductor device 500 according to embodiments of the disclosure. FIG. 6A shows a bottom view of the semiconductor device 500 as shown in FIG. 5. FIG. 6B shows a cross-sectional view of the semiconductor device 500 cut along the AA′ plane as shown in FIG. 5. FIG. 6C shows a cross-sectional view of the semiconductor device 500 cut along the BB′ plane as shown in FIG. 5. FIG. 6D shows a cross-sectional view of the semiconductor device 500 cut along the CC′ plane as shown in FIG. 5. FIG. 6E shows a cross-sectional view of the semiconductor device 500 cut along the DD′ plane as shown in FIG. 5.

In some embodiments, the first semiconductor wafer 501 includes a first substrate (not shown) and a first dielectric layer (not shown) on the first substrate. The first substrate may be made of silicon, although it may also be formed of other group III, group IV, and/or group V elements such as silicon, germanium, gallium, arsenic, or combinations thereof. In some embodiments, the first dielectric layer is made of silicon oxide, silicon nitride, silicon carbide, silicon oxynitride, combinations thereof, and/or the like.

In some embodiments, first electrical circuits are formed on the first substrate. The first electrical circuits may be any type of circuitry suitable for a particular application. For example, the first electrical circuits may include various N-type metal-oxide semiconductor (NMOS) and/or P-type metal-oxide semiconductor (PMOS) devices, capacitors, resistors, diodes, photo-diodes, fuses, and/or the like.

Referring back to FIG. 4, in some embodiments, as shown in FIG. 5, FIG. 6B, and FIG. 6C, a plurality of first metal lines 502 are formed in the first semiconductor wafer 501 in operation S420. For example, as shown in FIG. 5, the plurality of first metal lines 502 extend along the y-direction. The plurality of first metal lines 502 may be distributed in the x-direction. The x-direction may be perpendicular to the y-direction. In some embodiments, an angle between the x-direction and the y-direction is an acute angle.

In some embodiments, the plurality of first metal lines 502 are uniformly distributed in the x-direction. In some embodiments, the plurality of first metal lines 502 have multiple sets of different first-line pitches along the x-direction.

In some embodiments, as shown in FIG. 5 and FIG. 6B, each of the plurality of first metal lines 502 includes a plurality of first discrete portions 503 (e.g., 503a and 503b). In some embodiments, each of the plurality of first discrete portions 503 (e.g., 503a) is separated from adjacent first discrete portions (e.g., 503b).

In some embodiments, the plurality of first discrete portions 503 (e.g., 503a and 503b) are spaced from each other and uniformly distributed in the y-direction. In some embodiments, the plurality of first discrete portions 503 (e.g., 503a and 503b) have multiple sets of first discrete portion pitches along the y-direction.

Referring back to FIG. 4, in some embodiments, as shown in FIG. 5 and FIG. 6D, a plurality of first dummy lines 504 are formed in the first semiconductor wafer 501 in operation S430. For example, as shown in FIG. 5, the plurality of first dummy lines 504 extend along the x-direction. The plurality of first dummy lines 504 may be distributed in the y-direction. In some embodiments, dummy lines, such as the plurality of first dummy lines 504, are not electrically connected to other dummy lines or other metal lines. The dummy lines are not electrically connected to other semiconductor devices, such as N-type metal-oxide semiconductor (NMOS) and/or P-type metal-oxide semiconductor (PMOS) devices, capacitors, resistors, diodes, photo-diodes, fuses, and/or the like.

In some embodiments, as shown in FIG. 5, the plurality of first dummy lines 504 are positioned between adjacent first discrete portions 503 along the y-direction. For example, a first dummy line is positioned between two adjacent first discrete portions 503a and 503b.

In some embodiments, as shown in FIG. 5, each of the plurality of first dummy lines 504 includes a plurality of first discrete dummy portions 505 (e.g., 505a). In some embodiments, each of the plurality of first discrete dummy portions 505 (e.g., 505a) of a-first dummy line 504 is separated from adjacent first discrete dummy portions of the first dummy line 504.

In some embodiments, the plurality of first metal lines 502 and the plurality of first dummy lines 504 are formed by forming trenches or vias in the first semiconductor wafer 501 according to a designed pattern and then filling the trenches or vias with a conductive material. It will be understood by those skilled in the art that other methods of forming the plurality of first metal lines 502 and the plurality of first dummy lines 504 could be applied to the first semiconductor wafer 501.

In some embodiments, the plurality of first metal lines 502 and the plurality of first dummy lines 504 are made of the same conductive material. In some embodiments, the plurality of first metal lines 502 include copper, aluminum, gold, silver, silicon, combinations thereof, and/or the like. In some embodiments, the plurality of first dummy lines 504 include copper, aluminum, gold, silver, silicon, combinations thereof, and/or the like.

In some embodiments, the plurality of first metal lines 502 and the plurality of first dummy lines 504 have a thickness in a range from 1 μm to 20 μm. In some embodiments, the plurality of first metal lines 502 and the plurality of first dummy lines 504 have a thickness in a range from 2 μm to 10 μm.

Referring back to FIG. 4, in some embodiments, as shown in FIG. 5, a second semiconductor wafer 511 is provided in operation S440. A portion of the second semiconductor wafer 511 is illustrated in FIG. 5 to clarify and better illustrate the features of the present disclosure.

In some embodiments, the second semiconductor wafer 511 includes a second substrate (not shown) and a second dielectric layer (not shown) on the second substrate. The second substrate may be made of silicon, although it may also be formed of other group III, group IV, and/or group V elements such as silicon, germanium, gallium, arsenic, or combinations thereof. In some embodiments, the second dielectric layer is made of silicon oxide, silicon nitride, silicon carbide, silicon oxynitride, combinations thereof, and/or the like.

In some embodiments, second electrical circuits are formed on the second substrate. The second electrical circuits may be any type of circuitry suitable for a particular application. For example, the second electrical circuits may include various N-type metal-oxide semiconductor (NMOS) and/or P-type metal-oxide semiconductor (PMOS) devices, capacitors, resistors, diodes, photo-diodes, fuses, and/or the like.

Referring back to FIG. 4, in some embodiments, as shown in FIG. 5, FIG. 6A, FIG. 6B, and FIG. 6D, a plurality of second metal lines 512 are formed in the second semiconductor wafer 511 in operation S450. For example, the plurality of second metal lines 512 extend along the y-direction. The plurality of second metal lines 512 are distributed in the x-direction.

In some embodiments, as shown in FIG. 6E, each of the plurality of second metal lines 512 is positioned below a corresponding first metal line of the plurality of first metal lines 502. For example, each of the plurality of second metal lines 512 aligns with the corresponding first metal line of the plurality of first metal lines 502 along the z-direction.

In some embodiments, as shown in FIG. 5 and FIG. 6A, the plurality of second metal lines 512 are uniformly distributed in the x-direction. In some other embodiments, the plurality of second metal lines 512 have multiple sets of different second line pitches along the x-direction.

In some embodiments, each of the plurality of second metal lines 512 includes a plurality of second discrete portions 513 (e.g., 513a). In some embodiments, each of the plurality of second discrete portions 513 (e.g., 513a) is separated from adjacent second discrete portions 513. In some embodiments, as shown in FIG. 5 and FIG. 6B, the plurality of second discrete portions 513 (e.g., 513a) and the plurality of first discrete portions 503 (e.g., 503a) are alternately staggered along the first direction.

In some embodiments, the plurality of second discrete portions 513 are spaced from each other and uniformly distributed in the y-direction. In some embodiments, the plurality of second discrete portions 513 (e.g., 513a) have multiple sets of second discrete portion pitches along the y-direction.

Referring back to FIG. 4, in some embodiments, as shown in FIG. 5, FIG. 6A, and FIG. 6C, a plurality of second dummy lines 514 are formed in the second semiconductor wafer 511 in operation S460. For example, as shown in FIG. 5, the plurality of second dummy lines 514 extend along the x-direction. The plurality of second dummy lines 514 may be distributed in the y-direction. In some embodiments, dummy lines, such as the plurality of second dummy lines 514, are not electrically connected to each other or the metal lines. The dummy lines are not electrically connected to semiconductor devices, such as N-type metal-oxide semiconductor (NMOS) and/or P-type metal-oxide semiconductor (PMOS) devices, capacitors, resistors, diodes, photo-diodes, fuses, and/or the like.

In some embodiments, as shown in FIG. 5, the plurality of second dummy lines 514 are positioned between adjacent second discrete portions 513 along the y-direction. In some embodiments, a second dummy line is positioned between two adjacent second discrete portions 513.

In some embodiments, as shown in FIG. 5, each of the plurality of second dummy lines 514 includes a plurality of second discrete dummy portions 515 (e.g., 515a). In some embodiments, each of the plurality of second discrete dummy portions 515 (e.g., 515a) of a second dummy line 514 is separated from adjacent second discrete dummy portions of the second dummy line 514.

In some embodiments, the plurality of second metal lines 512 and the plurality of second dummy lines 514 are formed by forming trenches or vias in the second semiconductor wafer 511 according to a designed pattern and then filling the trenches or vias with a conductive material. It will be understood by those skilled in the art that other methods of forming the plurality of second metal lines 512 and the plurality of second dummy lines 514 could be applied to the second semiconductor wafer 511.

In some embodiments, the plurality of second metal lines 512 and the plurality of second dummy lines 514 are made of the same material. In some embodiments, the plurality of second metal lines 512 include copper, aluminum, gold, silver, silicon, combinations thereof, and/or the like. In some embodiments, the plurality of second dummy lines 514 include copper, aluminum, gold, silver, silicon, combinations thereof, and/or the like.

In some embodiments, the plurality of second metal lines 512 and the plurality of second dummy lines 514 have a thickness in a range from 1 μm to 20 μm. In some embodiments, the plurality of second metal lines 512 and the plurality of second dummy lines 514 have a thickness in a range from 2 μm to 10 μm.

Referring back to FIG. 4, in some embodiments, as shown in FIG. 5, FIG. 6B, and FIG. 6E, bonding connectors 521 are formed in operation S470.

In some embodiments, the bonding connectors 521 are formed to connect each of the plurality of first discrete portions 503 and adjacent first discrete portions 503 through the plurality of second discrete portions 513. For example, a first discrete portion 503a is connected to a corresponding second discrete portion 513a through a first bonding connector 521a. Then, the corresponding second discrete portion 513a is connected to the adjacent first discrete portion 503b through a second bonding connector 521b. In some embodiments, the plurality of first discrete portions 503 of a first metal line of the plurality of first metal lines 502 are electrically connected with each other.

In some embodiments, the bonding of bonding connectors 521 to the first semiconductor wafer 501 and the second semiconductor wafer 511 is achieved through a wafer-on-wafer (WoW) bonding process. In the wafer-on-wafer bonding process, the first semiconductor wafer 501 is bonded to the second semiconductor wafer 511, and the connectors 521 are bonded to the plurality of first metal lines 502 and the plurality of second metal lines 512 through metal-to-metal direct bonding. For example, a first discrete portion 503a and the corresponding second discrete portion 513a are bonded to the first bonding connector 521a through metal-to-metal direct bonding. In some embodiments, an annealing process is performed after the wafer-on-wafer bonding process to further strengthen the bonding between the first semiconductor wafer 501 and the second semiconductor wafer 511. Through the wafer-on-wafer bonding process, the bonding connector 521 may connect each of the plurality of first discrete portions 503 of a first metal line 502 and the plurality of second discrete portions 513 of a corresponding second metal line 512.

In some embodiments, the bonding connectors 521 are made of a conductive material such as solder, copper, aluminum, gold, nickel, silver, palladium, tin, a combination thereof, and/or the like.

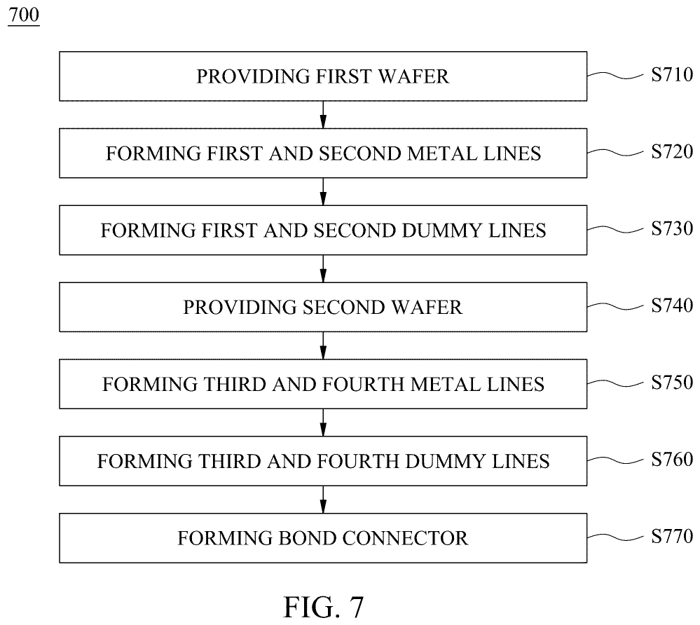

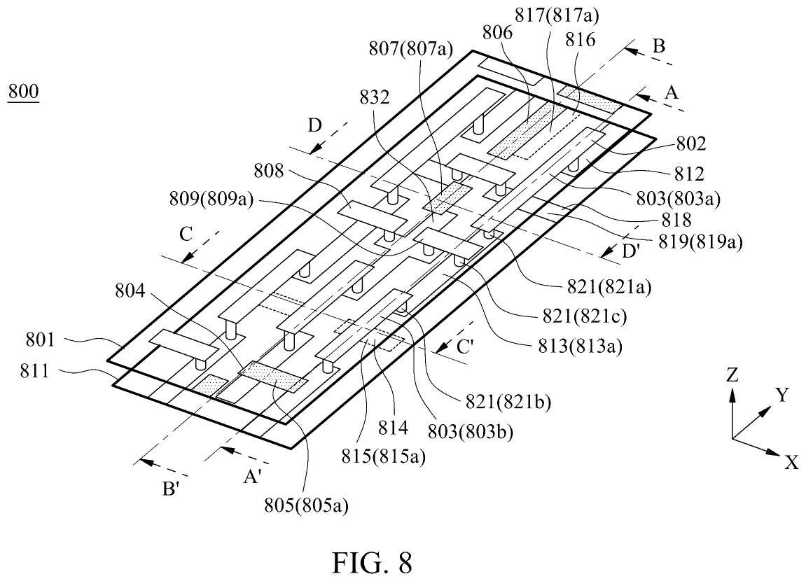

FIG. 7 illustrates a process flow 700 of manufacturing a semiconductor device according to embodiments of the disclosure. FIG. 8 shows a perspective view of a semiconductor device 800 according to embodiments of the disclosure. In some embodiments, as shown in FIG. 8, a first semiconductor wafer 801 is provided in operation S710. A portion of the first semiconductor wafer 801 is illustrated in FIG. 8 to clarify and better illustrate the features of the present disclosure.

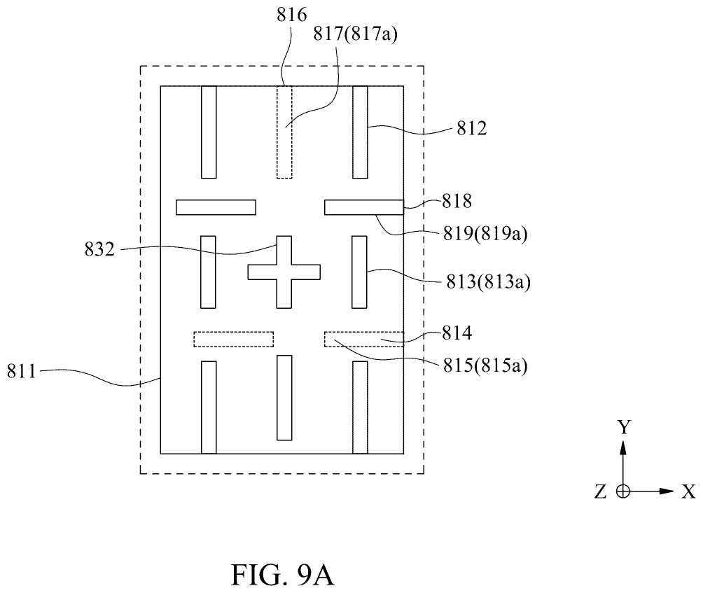

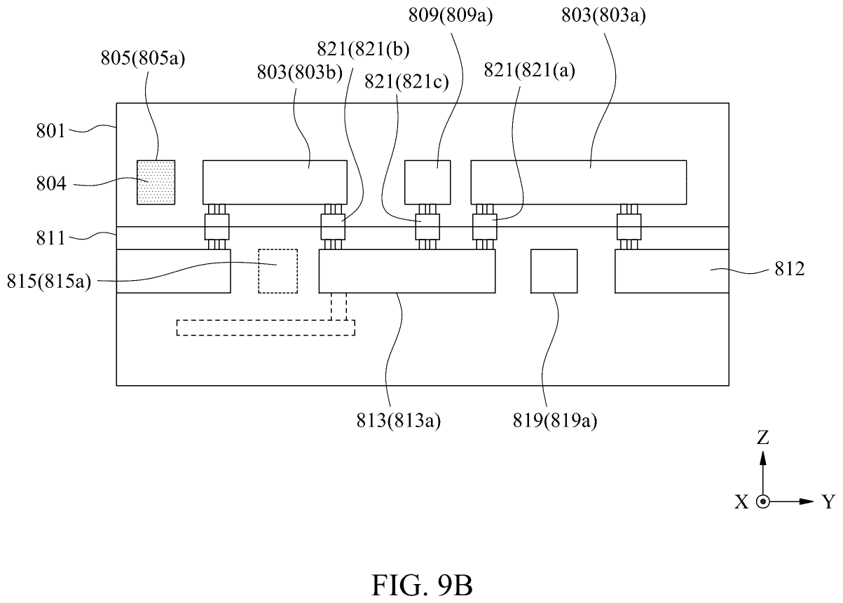

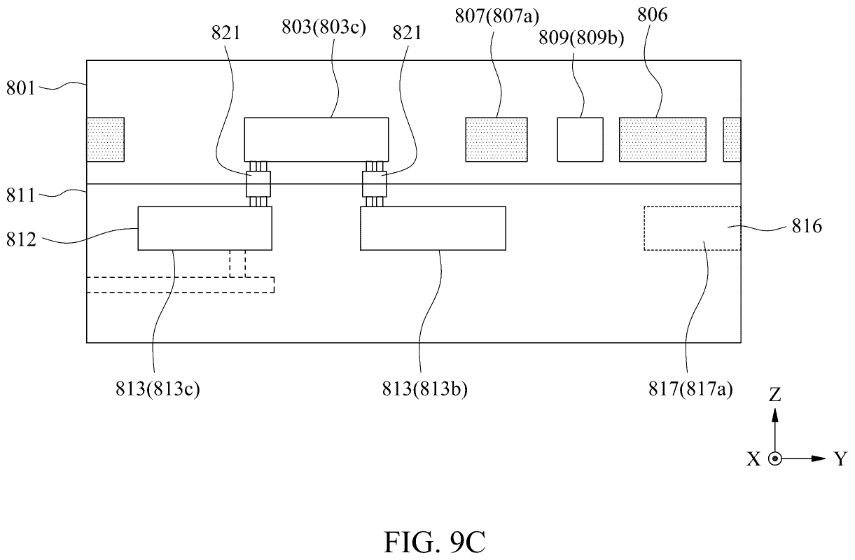

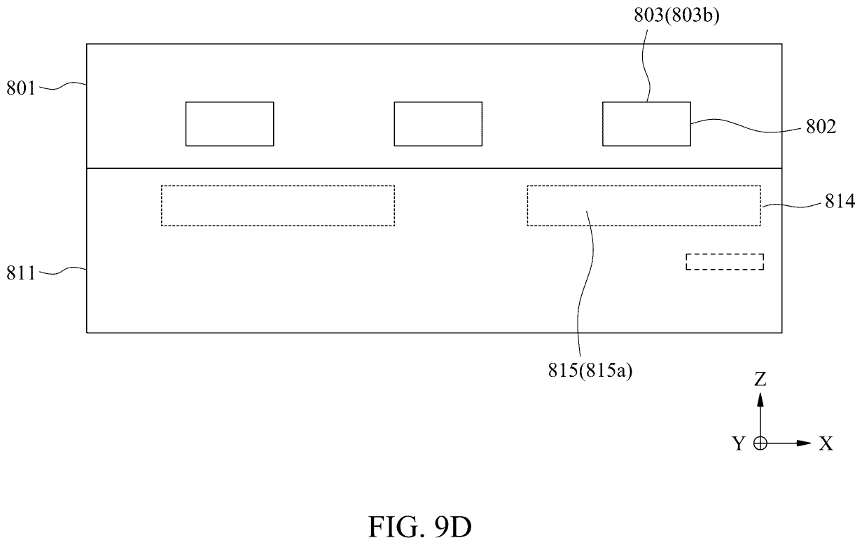

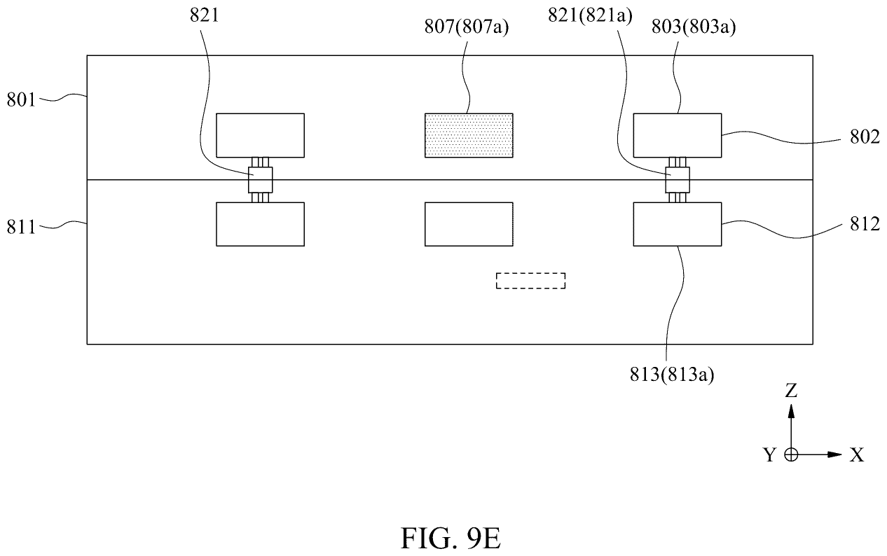

FIGS. 9A, 9B, 9C, 9D, and 9E show a bottom view and sectional views of the semiconductor device 800 according to embodiments of the disclosure. FIG. 9A shows a bottom view of the semiconductor device 800 as shown in FIG. 8. FIG. 9B shows a cross-sectional view of the semiconductor device 800 cut along the AA′ plane as shown in FIG. 8. FIG. 9C shows a cross-sectional view of the semiconductor device 800 cut along the BB′ plane as shown in FIG. 8. FIG. 9D shows a cross-sectional view of the semiconductor device 800 cut along the CC′ plane as shown in FIG. 8. FIG. 9E shows a cross-sectional view of the semiconductor device 800 cut along the DD′ plane as shown in FIG. 8.

In some embodiments, the first semiconductor wafer 801 includes a first substrate (not shown) and a first dielectric layer (not shown) on the first substrate. The first substrate may be made of silicon, although it may also be formed of other group III, group IV, and/or group V elements such as silicon, germanium, gallium, arsenic, or combinations thereof. In some embodiments, the first dielectric layer is made of silicon oxide, silicon nitride, silicon carbide, silicon oxynitride, combinations thereof, and/or the like.

In some embodiments, first electrical circuits are formed on the first substrate. The first electrical circuits may be any type of circuitry suitable for a particular application. For example, the first electrical circuits may include various N-type metal-oxide semiconductor (NMOS) and/or P-type metal-oxide semiconductor (PMOS) devices, capacitors, resistors, diodes, photo-diodes, fuses, and/or the like.

Referring back to FIG. 7, in some embodiments, as shown in FIG. 8, FIG. 9D, and FIG. 9E, a plurality of first metal lines 802 are formed in the first semiconductor wafer 801 in operation S720. For example, as shown in FIG. 8, the plurality of first metal lines 802 extend along the y-direction. The plurality of first metal lines 802 may be distributed in the x-direction. The x-direction may be perpendicular to the y-direction. In some other embodiments, an angle between the x-direction and the y-direction is an acute angle.

In some embodiments, the plurality of first metal lines 802 are uniformly distributed in the x-direction. In some embodiments, the plurality of first metal lines 802 have multiple sets of different first-line pitches along the x-direction.

In some embodiments, as shown in FIG. 8 and FIG. 9B, each of the plurality of first metal lines 802 includes a plurality of first discrete portions 803 (e.g., 803a and 803b). In some embodiments, each of the plurality of first discrete portions 803 (e.g., 803a) is separated from adjacent first discrete portions (e.g., 803b).

In some embodiments, the plurality of first discrete portions 803 (e.g., 803a and 803b) are spaced from each other and uniformly distributed in the y-direction. In some embodiments, the plurality of first discrete portions 803 (e.g., 803a and 803b) have multiple sets of first discrete portion pitches along the y-direction.

Alternatively or additionally, in some embodiments, a plurality of second metal lines 808 are formed in the first semiconductor wafer 801 in operation S720. For example, as shown in FIG. 8, the plurality of second metal lines 808 extend along the x-direction. The plurality of second metal lines 808 may be distributed in the y-direction. In some embodiments, as shown in FIG. 8, each of the plurality of second metal lines 808 is positioned between adjacent first discrete portions 803. In some embodiments, a second metal line 808 is positioned between two adjacent first discrete portions 803a and 803b.

In some embodiments, the plurality of second metal lines 808 are uniformly distributed in the y-direction. In some embodiments, the plurality of second metal lines 808 have multiple sets of different second line pitches along the y-direction.

In some embodiments, as shown in FIG. 8 and FIG. 9B, each of the plurality of second metal lines 808 includes a plurality of second discrete portions 809 (e.g., 809a). In some embodiments, each of the plurality of second discrete portions 809 (e.g., 809a) is separated from adjacent second discrete portions.

In some embodiments, the plurality of second discrete portions 809 (e.g., 809a) are uniformly distributed in the x-direction. In some embodiments, the plurality of second discrete portions 809 (e.g., 809a) have multiple sets of second discrete portion pitches along the x-direction.

Referring back to FIG. 7, in some embodiments, as shown in FIG. 8 and FIG. 9B, a plurality of first dummy lines 804 are formed in the first semiconductor wafer 801 in operation S730. For example, as shown in FIG. 8, the plurality of first dummy lines 804 extend along the x-direction. The plurality of first dummy lines 804 may be distributed in the y-direction.

In some embodiments, as shown in FIG. 8, the plurality of first dummy lines 804 are positioned between adjacent first discrete portions 803 along the y-direction. In some embodiments, a first dummy line is positioned between two adjacent first discrete portions 803a and 803b.

In some embodiments, as shown in FIG. 8, each of the plurality of first dummy lines 804 includes a plurality of first discrete dummy portions 805 (e.g., 805a). In some embodiments, each of the plurality of first discrete dummy portions 805 (e.g., 805a) of the first dummy line 804 is separated from adjacent first discrete dummy portions of the first dummy line 804.

In some embodiments, the plurality of first discrete dummy portions 805 (e.g., 805a) are uniformly distributed in the x-direction. In some embodiments, the plurality of first discrete dummy portions 805 (e.g., 805a) have multiple sets of first dummy portion pitches along the x-direction.

Alternatively or additionally, in some embodiments, as shown in FIG. 8, FIG. 9C, and FIG. 9E, a plurality of second dummy lines 806 are formed in the first semiconductor wafer 801 in operation S730. For example, as shown in FIG. 8, the plurality of second dummy lines 806 extend along the y-direction. The plurality of second dummy lines 806 may be distributed in the x-direction.

In some embodiments, as shown in FIG. 8, each of the plurality of second dummy lines 806 is positioned between adjacent first metal lines 802 along the x-direction.

In some embodiments, as shown in FIG. 8, each of the plurality of second dummy lines 806 includes a plurality of second discrete dummy portions 807 (e.g., 807a). In some embodiments, each of the plurality of second discrete dummy portions 807 (e.g., 807a) of the second dummy line 806 is separated from adjacent second discrete dummy portions of the second dummy line 806.

In some embodiments, the plurality of second discrete dummy portions 807 (e.g., 807a) are uniformly distributed in the y-direction. In some embodiments, the plurality of second discrete dummy portions 807 (e.g., 807a) have multiple sets of second dummy portion pitches along the x-direction.

In some embodiments, the plurality of first metal lines 802, the plurality of second metal lines 808, the plurality of first dummy lines 804, and the plurality of second dummy lines 806 are formed by forming trenches or vias in the first semiconductor wafer 801 according to a designed pattern and then filling the trenches or vias with a conductive material. It will be understood by those skilled in the art that other methods of forming the plurality of first metal lines 802, the plurality of second metal lines 808, the plurality of first dummy lines 804, and the plurality of second dummy lines 806 could be applied to the first semiconductor wafer 801.

In some embodiments, the plurality of first metal lines 802, the plurality of second metal lines 808, the plurality of first dummy lines 804, and the plurality of second dummy lines 806 are made of the same conductive material.

In some embodiments, the plurality of first metal lines 802 include copper, aluminum, gold, silver, silicon, combinations thereof, and/or the like. In some embodiments, the plurality of second metal lines 808 include copper, aluminum, gold, silver, silicon, combinations thereof, and/or the like. In some embodiments, the plurality of first dummy lines 804 include copper, aluminum, gold, silver, silicon, combinations thereof, and/or the like. In some embodiments, the plurality of second dummy lines 806 include copper, aluminum, gold, silver, silicon, combinations thereof, and/or the like.

Referring back to FIG. 7, in some embodiments, as shown in FIG. 8, a second semiconductor wafer 811 is provided in operation S740. A portion of the second semiconductor wafer 811 is illustrated in FIG. 8 to clarify and better illustrate the features of the present disclosure.

In some embodiments, the second semiconductor wafer 811 includes a second substrate (not shown) and a second dielectric layer (not shown) on the second substrate. The second substrate may be made of silicon, although it may also be formed of other group III, group IV, and/or group V elements such as silicon, germanium, gallium, arsenic, or combinations thereof. In some embodiments, the second dielectric layer is made of silicon oxide, silicon nitride, silicon carbide, silicon oxynitride, combinations thereof, and/or the like.

In some embodiments, second electrical circuits are formed on the second substrate. The second electrical circuits may be any type of circuitry suitable for a particular application. For example, the second electrical circuits include various N-type metal-oxide semiconductor (NMOS) and/or P-type metal-oxide semiconductor (PMOS) devices, capacitors, resistors, diodes, photo-diodes, fuses, and/or the like.

Referring back to FIG. 7, in some embodiments, as shown in FIG. 8, FIG. 9A, FIG. 9B, and FIG. 9C, a plurality of third metal lines 812 are formed in the second semiconductor wafer 811 in operation S750. For example, the plurality of third metal lines 812 extend along the y-direction. The plurality of third metal lines 812 are distributed in the x-direction.

In some embodiments, as shown in FIG. 9E, each of the plurality of third metal lines 812 is positioned below a corresponding first metal line of the plurality of first metal lines 802. For example, each of the plurality of third metal lines 812 aligns with the corresponding first metal line of the plurality of first metal lines 802 along the z-direction.

In some embodiments, as shown in FIG. 8 and FIG. 9A, the plurality of third metal lines 812 are uniformly distributed in the x-direction. In some other embodiments, the plurality of third metal lines 812 have multiple sets of different third line pitches along the x-direction.

In some embodiments, each of the plurality of third metal lines 812 includes a plurality of third discrete portions 813 (e.g., 813a). In some embodiments, each of the plurality of third discrete portions 813 (e.g., 813a) is separated from adjacent third discrete portions 813. In some embodiments, as shown in FIG. 8, FIG. 9B, and FIG. 9C, the plurality of second discrete portions 813 (e.g., 813a) and the plurality of first discrete portions 803 (e.g., 803a) are alternately staggered along the first direction.

In some embodiments, the plurality of third discrete portions 813 are spaced from each other and uniformly distributed in the y-direction. In some embodiments, the plurality of third discrete portions 813 (e.g., 813a) have multiple sets of third discrete portion pitches along the y-direction.

Alternatively or additionally, in some embodiments, a plurality of fourth metal lines 818 are formed in the second semiconductor wafer 811 in operation S750. For example, as shown in FIG. 8, the plurality of fourth metal lines 818 extend along the x-direction. The plurality of fourth metal lines 818 may be distributed in the y-direction. In some embodiments, as shown in FIG. 8, each of the plurality of fourth metal lines 818 is positioned between adjacent third discrete portions 813. In some embodiments, the fourth metal line 818 is positioned between two adjacent third discrete portions 813.

In some embodiments, the plurality of fourth metal lines 818 are uniformly distributed in the y-direction. In some embodiments, the plurality of fourth metal lines 818 have multiple sets of different fourth line pitches along the y-direction.

In some embodiments, as shown in FIG. 8 and FIG. 9A, each of the plurality of fourth metal lines 818 includes a plurality of fourth discrete portions 819 (e.g., 819a). In some embodiments, each of the plurality of fourth discrete portions 819 (e.g., 819a) is separated from adjacent fourth discrete portions.

In some embodiments, the plurality of fourth discrete portions 819 (e.g., 819a) are uniformly distributed in the x-direction. In some embodiments, the plurality of fourth discrete portions 819 (e.g., 819a) have multiple sets of fourth discrete portion pitches along the x-direction.

Referring back to FIG. 7, in some embodiments, as shown in FIG. 8, FIG. 9A, and FIG. 9D, a plurality of third dummy lines 814 are formed in the second semiconductor wafer 811 in operation S760. For example, as shown in FIG. 8, the plurality of third dummy lines 814 extend along the x-direction. The plurality of third dummy lines 814 may be distributed in the y-direction.

In some embodiments, as shown in FIG. 8, the plurality of third dummy lines 814 are positioned between adjacent third discrete portions 813 along the y-direction. In some embodiments, the third dummy line is positioned between two adjacent third discrete portions 813.

In some embodiments, as shown in FIG. 8, each of the plurality of third dummy lines 814 includes a plurality of third discrete dummy portions 815 (e.g., 815a). In some embodiments, each of the plurality of third discrete dummy portions 815 (e.g., 815a) of a third dummy line 814 is separated from adjacent third discrete dummy portions of the third dummy line 814.

In some embodiments, the plurality of third discrete portions 813 (e.g., 813a) are uniformly distributed in the y-direction. In some embodiments, the plurality of third discrete portions 813 (e.g., 813a) have multiple sets of third discrete portion pitches along the y-direction.

Alternatively or additionally, in some embodiments, as shown in FIG. 8, FIG. 9A, and FIG. 9C, a plurality of fourth dummy lines 816 are formed in the second semiconductor wafer 811 in operation S760. For example, as shown in FIG. 8, the plurality of fourth dummy lines 816 extend along the y-direction. The plurality of fourth dummy lines 816 may be distributed in the x-direction.

In some embodiments, as shown in FIG. 8 and FIG. 9A, each of the plurality of fourth dummy lines 816 is positioned between adjacent third metal lines 812 along the x-direction.

In some embodiments, each of the plurality of fourth dummy lines 816 includes a plurality of fourth discrete dummy portions 817 (e.g., 817a). In some embodiments, each of the plurality of fourth discrete dummy portions 817 (e.g., 817a) of a fourth dummy line 816 is separated from adjacent fourth discrete dummy portions of the fourth dummy line 816.

In some embodiments, the plurality of fourth discrete dummy portions 817 (e.g., 817a) are uniformly distributed in the y-direction. In some embodiments, the plurality of fourth discrete dummy portions 817 (e.g., 817a) have multiple sets of fourth dummy portion pitches along the x-direction.

In some embodiments, the plurality of third metal lines 812, the plurality of fourth metal lines 818, the plurality of third dummy lines 814, and the plurality of fourth dummy lines 816 are formed by forming trenches or vias in the second semiconductor wafer 811 according to a designed pattern and then filling the trenches or vias with a conductive material. It will be understood by those skilled in the art that other methods of forming the plurality of third metal lines 812, the plurality of fourth metal lines 818, the plurality of third dummy lines 814, and the plurality of fourth dummy lines 816 could be applied to the second semiconductor wafer 811.

In some embodiments, the plurality of third metal lines 812, the plurality of fourth metal lines 818, the plurality of third dummy lines 814, and the plurality of fourth dummy lines 816 are made of the same material.

In some embodiments, the plurality of third metal lines 812 include copper, aluminum, gold, silver, silicon, combinations thereof, and/or the like. In some embodiments, the plurality of fourth metal lines 818 include copper, aluminum, gold, silver, silicon, combinations thereof, and/or the like. In some embodiments, the plurality of third dummy lines 814 include copper, aluminum, gold, silver, silicon, combinations thereof, and/or the like. In some embodiments, the plurality of fourth dummy lines 816 include copper, aluminum, gold, silver, silicon, combinations thereof, and/or the like.

Referring back to FIG. 7, in some embodiments, as shown in FIG. 8, FIG. 9B, FIG. 9C and FIG. 9E, bonding connectors 821 are formed in operation S770.

In some embodiments, the bonding connectors 821 are formed to electrically connect the plurality of first discrete portions 803 through the plurality of third discrete portions 813. For example, a first discrete portion 803a is connected to a corresponding third discrete portion 813a through a first bonding connector 821a. Then, the corresponding third discrete portion 813a is connected to the adjacent first discrete portions 803b through a second bonding connector 821b. In some embodiments, the plurality of first discrete portions 803 of a first metal line of the plurality of first metal lines 802 are electrically connected with each other.

Alternatively or additionally, in some embodiments, the corresponding third discrete portion 813a is connected to a second discrete portion 809a through a third bonding connector 821c.

In some embodiments, the bonding connector 821 connects at least one of the plurality of third discrete portions 813 and the plurality of fourth discrete portions 819 to at least one of the plurality of first discrete portions 803 and the plurality of second discrete portions 809.

In some embodiments, as shown in FIG. 8 and FIG. 9A, a cross-shaped metal line 832 is formed in the second semiconductor wafer 811 in operation S750. In some embodiments, the cross-shaped metal line 832 is positioned between adjacent third metal lines 812. In some embodiments, the cross-shaped metal line 832 is positioned between adjacent fourth metal lines 818. In some embodiments, the second discrete portion 809a is connected to the cross-shaped metal line 832 through a bonding connector 821.

In some embodiments, the bonding of bonding connectors 821 to the first semiconductor wafer 801 and the second semiconductor wafer 811 is achieved through a wafer-on-wafer (WoW) bonding process. In the wafer-on-wafer bonding process, the first semiconductor wafer 801 is bonded to the second semiconductor wafer 811, and the bonding connectors 821 are bonded to the plurality of first metal lines 802 and the plurality of third metal lines 812 through metal-to-metal direct bonding. For example, the first discrete portion 803a and the corresponding third discrete portion 813a are bonded to the first bonding connector 821a through metal-to-metal direct bonding. In some embodiments, an annealing process is performed after the wafer-on-wafer bonding process to further strengthen the bonding between the first semiconductor wafer 801 and the second semiconductor wafer 811. Through the wafer-on-wafer bonding process, the bonding connector 821 may connect each of the plurality of first discrete portions 803 of the first metal line 802 and the plurality of third discrete portions 813 of a corresponding third metal line 812.

In some embodiments, the bonding connectors 821 are made of a conductive material such as solder, copper, aluminum, gold, nickel, silver, palladium, tin, a combination thereof, and/or the like.

Forming dummy lines between the spaced portions of the metal lines reduces the unbalanced wafer warpage and releases stress. The unbalanced wafer warpage and the stress may be further reduced by adding another set of dummy lines between the portions of the metal lines extending in a different direction. For example, for the 12-inch wafer with discrete metal lines having dummy lines inserted therebetween, the bow biases of the semiconductor devices 500 and 800 due to the warpage are smaller than 50 μm. The bow bias is reduced by embodiments of the disclosure to about 17% of bow bias in conventional devices. In other words, embodiments of the disclosure provide about 5.8× improvement in bow bias than conventional devices. In some embodiments, a density of the discrete metal lines and the dummy lines along the y-direction is substantially equal to a density of the discrete metal lines and the dummy lines along the x-direction, such that metal stress is reduced in both directions.

The novel ultra-thick metal (UTM) with cut-line structure and the manufacturing methods according to the present disclosure provide an improved metal routing structure and methods of forming the same. The disclosed structures and methods reduce the wafer warpage and balance the bow value of the wafer x-/y-direction warpage by releasing the stress compared to conventional techniques and configurations. Embodiments of the disclosure provide an improved ultra-thick metal (UTM) routing design with a cut-line structure for wafer-on-wafer (WoW) and/or other three-dimensional (3D) integrated circuit (IC) device structures that improves WoW and/or 3D IC device structure warpage issues due to the metal stress. Consequently, the performance of the wafer bonding and the silicon wafer backside process can be improved for manufacturing semiconductor devices.

An embodiment of the disclosure is a method of manufacturing a semiconductor device, including providing a first semiconductor substrate and forming a plurality of first metal lines extending along a first direction in the first semiconductor substrate. Each of the plurality of first metal lines includes a plurality of first discrete portions spaced along the first direction. The method further includes providing a second semiconductor substrate, and forming a second metal line below each of the plurality of first metal lines and extending along the first direction in the second semiconductor substrate. The second metal line includes a plurality of second discrete portions spaced along the first direction and the plurality of second discrete portions and the plurality of first discrete portions are alternately staggered along the first direction. The method also includes forming a bonding connector connecting the plurality of second discrete portions to a corresponding first metal line of the plurality of first metal lines. In an embodiment, the plurality of first metal lines and the second metal line are distributed along a second direction, and the first direction is perpendicular to the second direction. In an embodiment, the plurality of first metal lines are uniformly distributed in a second direction; and each second metal line is uniformly distributed in the second direction. In an embodiment, the second metal line aligns with the corresponding first metal line of the plurality of first metal lines along a third direction, and the third direction is perpendicular to the first direction and the second direction. In an embodiment, the plurality of first discrete portions are uniformly distributed along the first direction; and the plurality of second discrete portions are uniformly distributed along the first direction. In an embodiment, the method further includes forming a first dummy line in the first semiconductor substrate extending along a second direction and positioned between adjacent first discrete portions of the plurality of first discrete portions. In an embodiment, the first dummy line includes a plurality of first discrete dummy portions uniformly distributed along the second direction. In an embodiment, the method further includes forming a second dummy line in the second semiconductor substrate extending along the second direction and positioned between adjacent second discrete portions of the plurality of second discrete portions. In an embodiment, the second dummy line includes a plurality of second discrete dummy portions uniformly distributed along the second direction.

Another embodiment of the disclosure is a method of manufacturing a semiconductor device, including providing a first semiconductor substrate, and forming a plurality of first metal lines extending along a first direction and a plurality of second metal lines extending along a second direction in the first semiconductor substrate. Each of the plurality of first metal lines includes a plurality of first discrete portions spaced along the first direction, and each of the plurality of second metal lines includes a plurality of second discrete portions spaced along the second direction. The method further includes forming a first dummy line in the first semiconductor substrate extending along the second direction and positioned between adjacent first discrete portions of the plurality of first discrete portions, and forming a second dummy line in the first semiconductor substrate extending along the first direction and positioned between adjacent second discrete portions of the plurality of second discrete portions. In an embodiment, the first dummy line includes a plurality of first discrete dummy portions uniformly distributed along the first direction. In an embodiment, the second dummy line includes a plurality of second discrete dummy portions uniformly distributed along the second direction. In an embodiment, the method further includes providing a second semiconductor substrate, and forming a plurality of third metal lines extending along the first direction and a plurality of fourth metal lines extending along the second direction in the second semiconductor substrate. Each of the plurality of third metal lines includes a plurality of third discrete portions spaced along the first direction, each of the plurality of fourth metal lines includes a plurality of fourth discrete portions spaced along the second direction. The method further includes forming a bonding connector connecting at least one of the plurality of third discrete portions and the plurality of fourth discrete portions to at least one of the plurality of first discrete portions and the plurality of second discrete portions. In an embodiment, the method also includes forming a third dummy line in the second semiconductor substrate extending along the second direction and positioned between adjacent third discrete portions of the plurality of third discrete portions, and forming a fourth dummy line in the second semiconductor substrate extending along the first direction and positioned between adjacent fourth discrete portions of the plurality of fourth discrete portions. In an embodiment, the method further includes forming a cross-shaped metal line in the second semiconductor substrate positioned between adjacent third discrete portions of the plurality of third discrete portions and between adjacent fourth discrete portions of the plurality of fourth discrete portions. In an embodiment, the first direction is perpendicular to the second direction.

Another embodiment of the disclosure is a semiconductor device, including a first semiconductor substrate, and a plurality of first metal lines extending along a first direction in the first semiconductor substrate. Each of the plurality of first metal lines includes a plurality of first discrete portions spaced along a first direction. The semiconductor device further includes a second semiconductor substrate, and a second metal line below each of the plurality of first metal lines and extending along the first direction in the second semiconductor substrate. The second metal line includes a plurality of second discrete portions spaced along the first direction and the plurality of second discrete portions and the plurality of first discrete portions are alternately staggered along the first direction. The semiconductor device further includes a bonding connector connecting the plurality of second discrete portions to a corresponding first metal line of the plurality of first metal lines. In an embodiment, the plurality of first metal lines and the second metal line are distributed along a second direction, and the first direction is perpendicular to the second direction. In an embodiment, the plurality of first metal lines are uniformly distributed in a second direction, and each second metal line is uniformly distributed in the second direction. In an embodiment, the plurality of first discrete portions are uniformly distributed along the first direction, and the plurality of second discrete portions are uniformly distributed along the first direction.

Another embodiment of the disclosure is a method of manufacturing a semiconductor device, including providing a first semiconductor substrate, and forming a plurality of first metal lines extending along a first direction and a plurality of second metal lines extending along a second direction in the first semiconductor substrate. Each of the plurality of first metal lines includes a plurality of first discrete portions spaced along the first direction, and each of the plurality of second metal lines includes a plurality of second discrete portions spaced along the second direction. The method further includes providing a second semiconductor substrate, and forming a plurality of third metal lines extending along the first direction and a plurality of fourth metal lines extending along the second direction in the second semiconductor substrate. Each of the plurality of third metal lines includes a plurality of third discrete portions spaced along the first direction, each of the plurality of fourth metal lines includes a plurality of fourth discrete portions spaced along the second direction. The method further includes forming a bonding connector connecting at least one of the plurality of third discrete portions and the plurality of fourth discrete portions to at least one of the plurality of first discrete portions and the plurality of second discrete portions.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, comprising:
providing a first semiconductor substrate;
forming a plurality of first metal lines extending along a first direction in the first semiconductor substrate, wherein each of the plurality of first metal lines includes a plurality of first discrete portions spaced along the first direction;
providing a second semiconductor substrate;
forming a second metal line below each of the plurality of first metal lines and extending along the first direction in the second semiconductor substrate, wherein the second metal line includes a plurality of second discrete portions spaced along the first direction, and the plurality of second discrete portions and the plurality of first discrete portions are alternately staggered along the first direction; and
forming a bonding connector connecting the plurality of second discrete portions to a corresponding first metal line of the plurality of first metal lines.

2. The method according to claim 1, wherein:
the plurality of first metal lines and the second metal line are distributed along a second direction, and the first direction is perpendicular to the second direction.

3. The method according to claim 1, wherein:
the plurality of first metal lines are uniformly distributed in a second direction, and
each second metal line is uniformly distributed in the second direction.

4. The method according to claim 3, wherein:
the second metal line aligns with the corresponding first metal line of the plurality of first metal lines along a third direction, and the third direction is perpendicular to the first direction and the second direction.

5. The method according to claim 1, wherein:
the plurality of first discrete portions are uniformly distributed along the first direction, and
the plurality of second discrete portions are uniformly distributed along the first direction.

6. The method according to claim 1, further comprising:
forming a first dummy line in the first semiconductor substrate extending along a second direction and positioned between adjacent first discrete portions of the plurality of first discrete portions.

7. The method according to claim 6, wherein:
the first dummy line includes a plurality of first discrete dummy portions uniformly distributed along the second direction.

8. The method according to claim 6, further comprising:
forming a second dummy line in the second semiconductor substrate extending along the second direction and positioned between adjacent second discrete portions of the plurality of second discrete portions.

9. The method according to claim 8, wherein:
the second dummy line includes a plurality of second discrete dummy portions uniformly distributed along the second direction.

10. A method for manufacturing a semiconductor device, comprising:
providing a first semiconductor substrate;
forming a plurality of first metal lines extending along a first direction and a plurality of second metal lines extending along a second direction in the first semiconductor substrate, wherein each of the plurality of first metal lines includes a plurality of first discrete portions spaced along the first direction, each of the plurality of second metal lines includes a plurality of second discrete portions spaced along the second direction;
forming a first dummy line in the first semiconductor substrate extending along the second direction and positioned between adjacent first discrete portions of the plurality of first discrete portions; and
forming a second dummy line in the first semiconductor substrate extending along the first direction and positioned between adjacent second discrete portions of the plurality of second discrete portions.

11. The method according to claim 10, wherein:
the first dummy line includes a plurality of first discrete dummy portions uniformly distributed along the first direction.

12. The method according to claim 10, wherein:
the second dummy line includes a plurality of second discrete dummy portions uniformly distributed along the second direction.

13. The method according to claim 12, further comprising:
providing a second semiconductor substrate;
forming a plurality of third metal lines extending along the first direction and a plurality of fourth metal lines extending along the second direction in the second semiconductor substrate, wherein each of the plurality of third metal lines includes a plurality of third discrete portions spaced along the first direction, each of the plurality of fourth metal lines includes a plurality of fourth discrete portions spaced along the second direction; and
forming a bonding connector connecting at least one of the plurality of third discrete portions and the plurality of fourth discrete portions to at least one of the plurality of first discrete portions and the plurality of second discrete portions.

14. The method according to claim 13, further comprising:
forming a third dummy line in the second semiconductor substrate extending along the second direction and positioned between adjacent third discrete portions of the plurality of third discrete portions; and
forming a fourth dummy line in the second semiconductor substrate extending along the first direction and positioned between adjacent fourth discrete portions of the plurality of fourth discrete portions.

15. The method according to claim 13, further comprising:
forming a cross-shaped metal line in the second semiconductor substrate positioned between adjacent third discrete portions of the plurality of third discrete portions and between adjacent fourth discrete portions of the plurality of fourth discrete portions.

16. The method according to claim 10, wherein:
the first direction is perpendicular to the second direction.

17. A semiconductor device, comprising:
a first semiconductor substrate;
a plurality of first metal lines extending along a first direction in the first semiconductor substrate, wherein each of the plurality of first metal lines includes a plurality of first discrete portions spaced along a first direction;
a second semiconductor substrate;
a second metal line below each of the plurality of first metal lines and extending along the first direction in the second semiconductor substrate, wherein the second metal line includes a plurality of second discrete portions spaced along the first direction, and the plurality of second discrete portions and the plurality of first discrete portions are alternately staggered along the first direction; and
a bonding connector connecting the plurality of second discrete portions to a corresponding first metal line of the plurality of first metal lines.

18. The semiconductor device according to claim 17, wherein:
the plurality of first metal lines and the second metal line are distributed along a second direction, and
the first direction is perpendicular to the second direction.

19. The semiconductor device according to claim 17, wherein:
the plurality of first metal lines are uniformly distributed in a second direction, and
each second metal line is uniformly distributed in the second direction.

20. The semiconductor device according to claim 17, wherein:
the plurality of first discrete portions are uniformly distributed along the first direction, and
the plurality of second discrete portions are uniformly distributed along the first direction.
